(19) United States
(12) Patent Application Publication
(10) Pub. No.: US 2024/0164004 A1
(43) Pub. Date: May 16, 2024

(54) TARGET MATERIAL TRANSFER SYSTEM COMPONENTS AND METHODS OF MAKING THE SAME

(71) Applicant: ASML Netherlands B.V., Veldhoven (NL)

(72) Inventors: Dietmar Uwe Herbert Trees, San Diego, CA (US); Theodorus Wilhelmus Driessen, Asten-Heusden (NL); Benjamin Andrew Sams, San Diego, CA (US); Edgardo Zamora Atencio, Escondido, CA (US); Ondrej Dvorak, San Diego, CA (US)

(21) Appl. No.: 18/280,917

(22) PCT Filed: Feb. 10, 2022
(86) PCT No.: PCT/EP2022/053207

§ 371 Date: Sep. 7, 2023

Related U.S. Application Data
(60) Provisional application No. 63/158,411, filed on Mar. 9, 2021.

(51) Int. Cl. H05G 2/00; G03F 7/00

(52) U.S. Cl. CPC H05G 2/006; G03F 7/70033; H05G 2/008

(57) ABSTRACT

A component for a target material transfer system for a laser-produced plasma radiation source and a method of manufacturing such a component are disclosed. The component, which may, for example, be a target material transfer line, a freeze valve, or a flow restrictor, or some combination of this functionality, is made up of a glass capillary body sealed with glass-to-metal seals at both of its ends to a respective metal fitting. The method of manufacturing involves heating the ends of the glass capillary and then forming them to conform with, and forming a glass-to-metal seal with, the interior contours of the respective channels in each of the metal fittings.

### CROSS REFERENCE TO RELATED APPLICATIONS

This application claims priority to U.S. Application No. 63/158,411, filed Mar. 9, 2021, titled TARGET MATERIAL TRANSFER SYSTEM COMPONENTS AND METHODS OF MAKING THE SAME, which is incorporated herein in its entirety by reference.

### FIELD

The present disclosure relates to components for a target material transfer system for a supplying a target material such as molten tin in a laser-produced plasma radiation source, including transfer lines, freeze valves, and flow restrictors. The present disclosure also relates to methods and equipment for making such components.

### BACKGROUND

A lithographic apparatus is a machine constructed to apply a desired pattern onto a substrate. A lithographic apparatus can be used, for example, in the manufacture of integrated circuits. A lithographic apparatus may, for example, project a pattern from a patterning device (e.g., a mask) onto a layer of radiation-sensitive material such as photoresist, or simply resist, provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength greater that 4-20 nm. Herein, the term “light” may be applied to all electromagnetic radiation even though its wavelength may not be in the visible part of the spectrum.

EUV radiation may be produced using a plasma. A system for producing EUV radiation may include a laser for exciting a target material to provide the plasma, and a source collector module for containing the plasma. The plasma may be created, for example, by directing a laser beam at a target material, such as small volumes (e.g., droplets or particles) of a suitable material (e.g. tin (Sn)), or a stream of a suitable gas or vapor, such as Xe gas or Li vapor. The resulting plasma emits radiation, e.g., EUV radiation, which is collected using a radiation collector. The radiation collector may be a mirrored normal incidence radiation collector, which receives the radiation and focuses the radiation into a beam. The source collector module may include an enclosing structure or chamber arranged to provide a near vacuum environment to support the plasma. Such a radiation system is typically termed a laser produced plasma (LPP) source.

The target material may be directed toward a point of interception with the laser beam by a droplet generator, also referred to as a target material emitter. The droplet generator can include a nozzle assembly to emit the target material as droplets.

The elements of a target material delivery system such as the droplet generator and one or more reservoirs for holding molten target material are interconnected by a target material transfer system including one or more target material transfer components including target material transfer lines, valves, and flow restrictors providing controllable fluid communication between the droplet generator nozzle, reservoirs, gas sources, etc. A target material transfer component needs to be compatible with the target material and resistant to internal pressure. Such internal pressures may be on the order of 275 bar (4000 psi), 700 bar (10152 psi), and even 1400 bar (20305 psi). Here, “compatible” includes “resistant to deterioration by,” including deterioration by erosion, corrosion, dissolution, and other mechanical and chemical mechanisms.

Conventionally, target material transfer components are welded assemblies made from refractory metals. The welds are susceptible to cracking necessitating removal and replacement far earlier than the desired design life of the component. Such welded assemblies are also very expensive. Similarly, the target material transfer components may be made from welded tantalum/tungsten materials and may have a shortened lifetime due to oxygen embrittlement. Also, most commonly used metals, such as steel and nickel alloys, are not compatible with a target material such as molten tin. This means that suitable metal tubing for high pressure applications is not readily available in the required inner and outer diameters. Short target material transfer system components are machined from solid rods, limiting the available length and minimum inner diameter.

These target material transfer system components provide selectable fluid communication in the sense that they may include valve structures to selectably permit and prevent fluid communication. For molten tin, one type of valve that may be used is a so-called freeze valve. A freeze valve allows selectable isolation and connection of a portion of the system by freezing the target material (valve closed) and thawing it (valve open). Such freeze valves do not require any mechanical actuation to change the state of the freeze valve. Properly designed freeze valves can seal against high pressure.

In a freeze valve, the thermal mass that needs to be heated and cooled to operate the freeze valve, especially in high pressure applications with thick-walled tubing, does not allow for a rapid transition of the state of the freeze valve. Conventional designs necessitate a large amount of heat transfer to freeze and melt the target material. For high pressure applications, they also necessitate larger wall thicknesses (outer diameters) thereby increasing the thermal mass of the valve body and so the time required to cycle the freeze valve.

Also, thermal management of the freeze valves can be complicated by the proximity of heated or cooled components. Excessive heat transfer from a heated component to the freeze valve may prevent sufficient freezing. The excessive heat transfer is exacerbated when the freeze valve is made of a high thermal conductivity material such as molybdenum. Molybdenum is used in systems using tin as a target material because of its compatibility with molten tin, but molybdenum is also one of the best heat conductors, making thermal management more challenging.

As a further issue is that when the freeze valve is fabricated from a block of molybdenum it will expand when heated and displace the fittings to which it is connected. For some implementations it would be advantageous if the freeze valve itself would accommodate any thermal displacement so that fittings attached to the freeze valve would not be forcibly displaced from their room temperature position.

The functioning of the freeze valve depends on target material in being in the valve. If there is no target material in the valve, the valve cannot close, potentially causing a malfunction of the system and posing a risk of damage or injury. When the freeze valve is made of an opaque, electrically-conductive material there is no straightforward way to determine if the freeze valve is filled with target material. For some implementations it would be advantageous if the presence or absence of target material in the freeze valve could be easily determined or confirmed.

These target material transfer lines may also include flow restrictors that restrict the passage of fluid. It would be advantageous if these flow restrictors can be fabricated without welds.

### SUMMARY

The following presents a simplified summary of one or more embodiments in order to provide a basic understanding of the embodiments. This summary is not an extensive overview of all contemplated embodiments and is not intended to identify key or critical elements of all embodiments nor delineate the scope of any or all embodiments. Its sole purpose is to present some concepts of one or more embodiments in a simplified form as a prelude to the more detailed description that is presented later.

According to an aspect of an embodiment, the components of a target material transfer system including target material transfer lines in an EUV radiation source are made in part from a glass material such as borosilicate glass or aluminosilicate glass.

According to another aspect of an embodiment, a method of making the target material transfer system components is disclosed.

According to an aspect of an embodiment, there is disclosed a component for a target material supply system for an EUV radiation source may comprise a first fitting made of metal and having a first channel, a tube member made of glass and having a first end disposed within the first channel and attached to an interior of the first channel by a first glass-to-metal seal, and a second fitting made of metal having a second channel, the tube member having a second end disposed within the second channel and attached to an interior of the second channel by a second glass-to-metal seal.

The first fitting may comprise a metal such as molybdenum or tantalum and the second fitting may comprise a metal such as molybdenum or tantalum. The tube member may comprise borosilicate glass. The tube member may comprise aluminosilicate glass. The component may further comprise an electrically conductive coil disposed around an intermediate longitudinal portion of the tube member.

The coil may be adapted to provide ohmic heating of the tube member and any contents of the tube member. The coil may be to couple RF energy into any electrically conductive contents of the tube member. The coil may comprise a jacket adapted to carry a cooling fluid. The component may further comprise a metallic cladding layer disposed around the tube member.

The tube member may have a longitudinal section with a narrowed cross section. The longitudinal section may be straight. The longitudinal section may be helical. The longitudinal section may be flexible.

The component may further comprise an inspection system arranged to inspect the tube member. The inspection system may comprise a light source arranged to direct light at the tube member and a sensor arranged to receive light from the light source that has passed through the tube member to determine whether an opaque substance is in the tube member. The inspection system may be arranged to determine by a variation in capacitance whether an electrically conductive substance is within the tube member. The inspection system may be arranged to determine by a variation in inductance whether an electrically conductive substance is within the tube member.

According to another aspect of an embodiment, there is disclosed a target material transfer system for transferring molten target material from at least one reservoir to a droplet generator, the target material delivery system comprising at least one component including a first fitting made of metal and having a first channel, a tube member made of glass and having a first end disposed within the first channel and attached to an interior of the first channel by a first glass-to-metal seal, and a second fitting made of metal having a second channel, the tube member having a second end disposed within the second channel and attached to an interior of the second channel by a second glass-to-metal seal.

The first fitting may comprise molybdenum and the second fitting may comprise molybdenum. The tube member may comprise borosilicate glass. The tube member may comprise aluminosilicate glass. The a target material transfer system may further comprise an electrically conductive coil disposed around an intermediate longitudinal portion of the tube member.

The coil may be adapted to provide ohmic heating of the tube member and any contents of the tube member. The coil may be to couple RF energy into any electrically conductive contents of the tube member. The coil may comprise a jacket adapted to carry a cooling fluid. The component may further comprise a metallic cladding layer disposed around the tube member.

The tube member has a longitudinal section with a narrowed cross section. The longitudinal section may be straight. The longitudinal section may be helical. The longitudinal section may be flexible.

The a target material transfer system may further comprise an inspection system arranged to inspect the tube member. The inspection system may comprise a light source arranged to direct light at the tube member and a sensor arranged to receive light from the light source that has passed through the tube member to determine whether an opaque substance is in the tube member. The inspection system may be arranged to determine by a variation in capacitance whether an electrically conductive substance is within the tube member. The inspection system may be arranged to determine by a variation in inductance whether an electrically conductive substance is within the tube member.

According to another aspect of an embodiment, there is disclosed a method of manufacturing a component for a target material transfer system, the method comprising (a) disposing a first end of a glass capillary in a channel of a first metal fitting, (b) heating the first metal fitting, (c) applying a pressure to the glass capillary such that the first end of the glass capillary conforms to the shape of, and forms a direct glass-to-metal seal with, an interior surface of the channel of the first metal fitting, (d) disposing a second end of the glass capillary in a channel of a second metal fitting, (e) heating the second metal fitting, and (f) applying a pressure to the glass capillary such that the second end of the glass capillary conforms to the shape of, and forms a direct glass-to-metal seal with, an interior surface of the channel of the second metal fitting. The method may be performed in an order (a) through (f). The method may be performed in an order (a), (d), (b), (c) (e) and (f). Step (b) may be performed together with (d) and (c) may be performed together with (f).

At least a portion of the channel may be frustum-shaped. Step (a) may comprise disposing the glass capillary in the form of a tube with a constant diameter and wherein (b) and (c) change the shape of the capillary. Step (c) may comprise applying an internal pressure to the glass capillary by sealing the second end of the glass capillary and pumping a gas into the first end of the glass capillary. Step (c) may comprise applying an external pressure to the glass capillary by applying opposing compressive forces to at least one of portions of the glass capillary extending from the channel and one or both ends of the glass capillary. The opposing compressive forces are applied along a longitudinal direction of the glass capillary. The method may further comprise inserting a rigid element into the glass capillary before applying the external pressure. The pressure may be applied to the glass capillary during and/or after heating the metal fitting.

A coefficient of thermal expansion of the glass capillary may be chosen to be compatible with the coefficient of thermal expansion of the metal fitting over a temperature range comprising an operational temperature range of the component and a manufacturing temperature range of the component.

The metal fitting may comprise molybdenum, tantalum, tungsten, or a metal alloy and/or the glass capillary may comprise a borosilicate, an aluminosilicate, or other transparent ceramic or quartz. Thus, the term “glass” is used broadly herein to refer to a solid transparent material. At least a portion of the metal fitting may comprise a metal oxide layer. The method may further comprise annealing the glass capillary and/or the metal fitting after allowing the metal fitting to cool. Heating the metal fitting may comprise induction heating the first and second metal fittings. The method may further comprise providing a flow of an inert gas during the induction heating, the flow directed to the glass capillary. The step of heating the metal fitting may comprise heating the metal fitting in an inert atmosphere or a relative vacuum. Step (a) may comprise disposing the glass capillary in the channel of the first metal fitting such that the glass capillary protrudes from both ends of the channel. At least one portion of the glass capillary that protrudes from the metal fitting may be removed by at least one of: sanding, grinding, polishing, and/or cutting.

According to another aspect of an embodiment, there is disclosed a component for a target material transfer system for a laser-produced plasma radiation source, the component comprising a glass capillary, a first metal fitting for coupling a first end of the glass capillary to a first portion of the target material transfer system, the first end of the glass capillary being conformed to a shape of a channel of the first metal fitting, and wherein the first end of the glass capillary forms a direct glass-to-metal seal with the channel of the first metal fitting, and a second metal fitting for coupling a second end of the glass capillary to a second portion of the target material transfer system, the second end of the glass capillary being conformed to a shape of a channel of the second metal fitting, and wherein the second end of the glass capillary forms a direct glass-to-metal seal with the channel of the first metal fitting.

The glass capillary of the target material transfer system component may have a first lengthwise portion with a first wall thickness and a second lengthwise portion with a second wall thickness different from the first wall thickness. The glass capillary may comprise a transitional region between the first lengthwise portion and the second lengthwise portion having a wall thickness varying between the first wall thickness and the second wall thickness. The glass capillary may comprises a borosilicate, an aluminosilicate, or quartz.

The shape of the channel in the first metal fitting may include a uniformly cylindrical section and/or a frustum-shaped section. The component may be manufactured according to a method including disposing an end of the glass capillary in the channel of the first metal fitting, heating the first metal fitting, applying a pressure to the end of the glass capillary such that the glass capillary conforms to the shape of, and forms a direct glass-to-metal seal with, the channel of the first metal fitting, disposing the other end of the glass capillary in the channel of a second metal fitting, heating the second metal fitting, and applying a pressure to the end of the glass capillary such that the glass capillary conforms to the shape of, and forms a direct glass-to-metal seal with, the channel of the second metal fitting.

According to another aspect of an embodiment, there is disclosed an apparatus for forming a component for a target material transfer system for a laser-produced plasma radiation source, the apparatus comprising a tool adapted to hold a metal fitting having a glass tube inserted in a channel in the metal fitting, an inductive coil adapted to heat the metal fitting by inductive heating, a gas conduit adapted to apply pneumatic pressure to the fitting and glass tube, and a press adapted to apply a force to the metal fitting and the glass tube to force the glass tube into contact with the channel.

Further features and exemplary aspects of the embodiments, as well as the structure and operation of various embodiments, are described in detail below with reference to the accompanying drawings. It is noted that the embodiments are not limited to the specific embodiments described herein.

Such embodiments are presented herein for illustrative purposes only. Additional embodiments will be apparent to persons skilled in the relevant art(s) based on the teachings contained herein.

### BRIEF DESCRIPTION OF THE DRAWINGS

The accompanying drawings, which are incorporated herein and form part of the specification, illustrate the embodiments and, together with the description, further explain the principles of the embodiments and enable a person skilled in the relevant arts to make and use the embodiments.

FIG. 1 depicts a lithographic system comprising a lithographic apparatus and a radiation source embodying the present invention;

FIG. 2 is a stylized schematic diagram of a target material transfer system for a lithographic apparatus.

FIG. 3 is a cross section of a conventional freeze valve.

FIG. 4 is a partially cutaway side view of a component for a target material transfer system according to an aspect of an embodiment.

FIG. 5 is a partially cutaway side view of a component for a target material transfer system according to an aspect of an embodiment.

FIGS. 6a and 6b are partially cutaway side views of a component for a target material transfer system according to an aspect of an embodiment.

FIGS. 7a and 7b are partially cutaway side views of components for a target material transfer system, including heating elements, according to an aspect of an embodiment.

FIGS. 8a and 8b are partially cutaway side views of components for a target material transfer system wherein the components are shown as having a constant internal diameter for simplicity, including inspection systems, according to an aspect of an embodiment.

FIGS. 9a to 9g depict steps in a method for manufacturing a component for a target material transfer system for a droplet generator for a laser-produced plasma radiation source, according to an embodiment of the invention.

FIG. 10 is a flowchart of the steps in a method for fabricating a component for a target material transfer system according to an aspect of an embodiment.

FIG. 11 is a flowchart of the steps in a method for fabricating a component for a target material transfer system according to an aspect of an embodiment.

FIG. 12 is a diagram showing fabrication of a target material transfer system component according to one aspect of an embodiment.

FIG. 13 is a diagram showing fabrication of a target material transfer system component according to one aspect of an embodiment.

FIG. 14 is a schematic diagram of an apparatus for making target material transfer system components according to an aspect of an embodiment.

The features and exemplary aspects of the embodiments will become more apparent from the detailed description set forth below when taken in conjunction with the drawings, in which like reference characters identify corresponding elements throughout. In the drawings, like reference numbers generally indicate identical, functionally similar, and/or structurally similar elements. Unless otherwise indicated, the drawings provided throughout the disclosure should not be interpreted as to-scale drawings.

### DETAILED DESCRIPTION

This specification discloses one or more embodiments that incorporate the features of the present invention. The disclosed embodiment(s) merely exemplify the present invention. The scope of the invention is not limited to the disclosed embodiments. The present invention is instead delimited by the claims appended to this descriptive portion of the specification.

The embodiments described, and references in the specification to “one embodiment,” “an embodiment,” “an exemplary embodiment,” “an example embodiment,” etc., indicate that the embodiments described may include a particular feature, structure, or characteristic, but not every embodiment necessarily includes the particular feature, structure, or characteristic. Moreover, such phrases are not necessarily all referring to the same embodiment. Further, when a particular feature, structure, or characteristic is described in connection with an embodiment, it is understood that it is within the knowledge of one skilled in the art to implement such feature, structure, or characteristic in connection with other embodiments whether or not explicitly described.

The use of spatially relative terms is intended to encompass different orientations of the components in use or operation in addition to the orientation depicted in the figures. The components may be otherwise oriented (rotated 90 degrees or at other orientations) and the spatially relative descriptors used herein may likewise be interpreted accordingly.

The term “about” or “substantially” or “approximately” as used herein indicates the value of a given quantity that can vary based on a particular technology. Based on the particular technology, the term “about” or “substantially” or “approximately” can indicate a value of a given quantity that varies within, for example, 1-15% of the value (e.g., ±1%, ±2%, ±5%, ±10%, or ±15% of the value).

Before describing any embodiments in more detail, however, it is useful to describe an example environment in which embodiments of the present disclosure may be implemented.

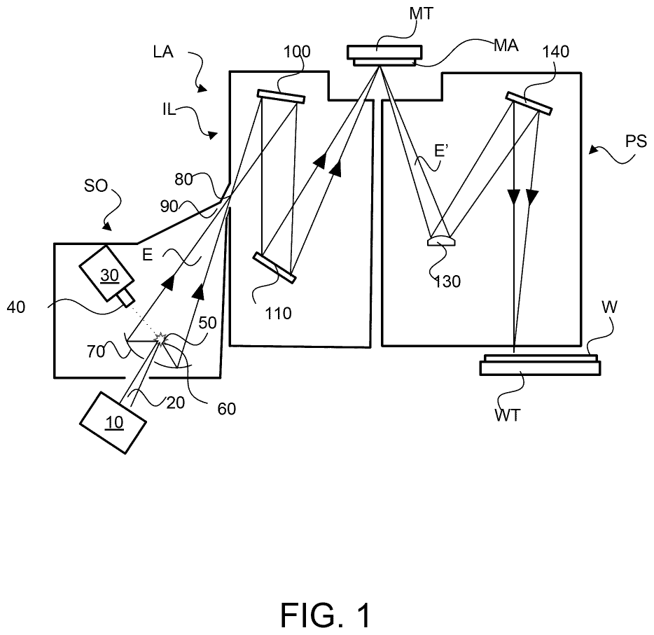

FIG. 1 shows a lithographic system comprising a radiation source SO and a lithographic apparatus LA. The radiation source SO is configured to generate an EUV radiation beam E and to supply the EUV radiation beam E to the lithographic apparatus LA. The lithographic apparatus LA comprises an illumination system IL, a support structure MT configured to support a patterning device MA (e.g., a mask or reticle), a projection system PS and a substrate table WT configured to support a substrate W.

The illumination system IL is configured to condition the EUV radiation beam E before the EUV radiation beam E is incident upon the patterning device MA. Thereto, the illumination system IL may include a facetted field mirror device 100 and a facetted pupil mirror device 110. The faceted field mirror device 10 and faceted pupil mirror device 110 together provide the EUV radiation beam E with a desired cross-sectional shape and a desired intensity distribution. The illumination system IL may include other mirrors or devices in addition to, or instead of, the faceted field mirror device 100 and faceted pupil mirror device 110.

After being thus conditioned, the EUV radiation beam E interacts with the patterning device MA. As a result of this interaction, a patterned EUV radiation beam E′ is generated. The projection system PS is configured to project the patterned EUV radiation beam B′ onto the substrate W. For that purpose, the projection system PS may comprise a one or more mirrors 130, 140 which are configured to project the patterned EUV radiation beam E′ onto the substrate W held by the substrate table WT. The projection system PS may apply a reduction factor to the patterned EUV radiation beam E′, thus forming an image with features that are smaller than corresponding features on the patterning device MA. For example, a reduction factor of four or eight may be applied. Although the projection system PS is illustrated as having only two mirrors 130, 140 in FIG. 1, the projection system PS may include a different number of mirrors (e.g., six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e., a small amount of gas (e.g., hydrogen) at a pressure well below atmospheric pressure, may be provided in the radiation source SO, in the illumination system IL, and/or in the projection system PS.

The radiation source SO shown in FIG. 1 is, for example, of a type which may be referred to as a laser produced plasma (LPP) source. A laser system 10, which may, for example, include a CO 2 laser, is arranged to deposit energy via a laser beam 20 into a target material, such as tin (Sn) which is provided from, e.g., a target material emitter (droplet generator) 30. Although the target material sometimes used to herein as an example is tin, any suitable target material may be used. The target material may, for example, be in liquid form, and may, for example, be a metal or alloy. The target material emitter 30 may comprise a nozzle 40 configured to direct target material, e.g., in the form of droplets, along a trajectory towards a plasma formation region 50. The laser beam 20 is incident upon the target material at the plasma formation region 50. The deposition of laser energy into the target material creates a plasma 60 at the plasma formation region 50. Radiation, including EUV radiation, is emitted from the plasma 60 during de-excitation and recombination of electrons with ions of the plasma.

The EUV radiation from the plasma is collected and focused by a collector 70. Collector 70 comprises, for example, a near-normal incidence radiation collector 70 (sometimes referred to more generally as a normal-incidence radiation collector). The collector 70 may have a multilayer mirror structure which is arranged to reflect EUV radiation (e.g., EUV radiation having a desired wavelength such as 13.5 nm). The collector 70 may have an ellipsoidal configuration, having two focal points. A first one of the focal points may be at the plasma formation region 50, and a second one of the focal points may be at an intermediate focus 80, as discussed below.

The laser system 10 may be spatially separated from the radiation source SO. Where this is the case, the laser beam 20 may be passed from the laser system 10 to the radiation source SO with the aid of a beam delivery system (not shown) comprising, for example, suitable directing mirrors and/or a beam expander, and/or other optics. The laser system 10, the radiation source SO and the beam delivery system may together be considered to be a radiation system.

Radiation that is reflected by the collector 70 forms the EUV radiation beam E. The EUV radiation beam E is focused at intermediate focus 80 to form an image at the intermediate focus 80 of the plasma present at the plasma formation region 60. The image at the intermediate focus 80 acts as a virtual radiation source for the illumination system IL. The radiation source SO is arranged such that the intermediate focus 80 is located at or near to an opening 90 in an enclosing structure of the radiation source SO.

Although FIG. 1 depicts the radiation source SO as a laser produced plasma (LPP) source, any suitable source such as a discharge produced plasma (DPP) source or a free electron laser (FEL) may be used to generate EUV radiation. The target material emitter 30 is also referred to as a droplet generator or droplet generator assembly.

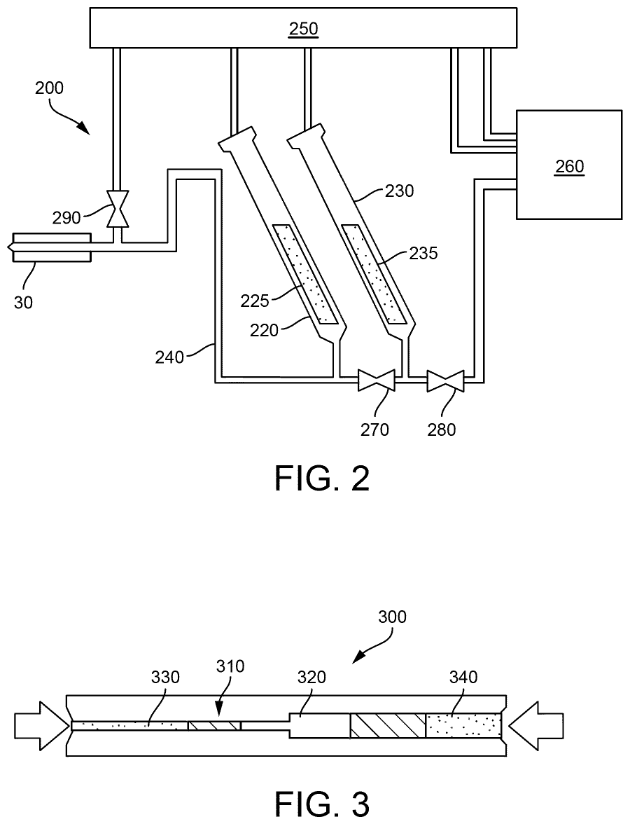

As shown in FIG. 2 the lithographic apparatus LA also includes a target material transfer system 200 for supplying target material to the target material emitter 30. The target material transfer system 200 may include a primary reservoir 220 containing a quantity 225 of molten target material. The target material transfer system 200 may also include a refill reservoir 230 containing a quantity 235 of molten target material. These items are connected by target material transfer lines of which target material transfer line 240 is an example.

The target material transfer system 200 may also include a gas and vacuum delivery system 250 that supplies gas and/or applies vacuum to parts of the target material transfer system 200. The target material transfer system 200 may also include a refill and priming system 260 used in refill operations and for priming the target material transfer system 200, for example, at start up.

The target material transfer system 200 may also include one or more valves to control flow of molten target material through the system. For example, the target material transfer system 200 in FIG. 2 may include a primary valve 270 interposed between the primary reservoir 220 and the refill reservoir 230. The target material transfer system 200 in FIG. 2 may also include a refill valve 280 interposed between the refill reservoir 230 and the refill and priming system 260. The target material transfer system 200 in FIG. 2 may also include a service valve 290 interposed between gas and vacuum delivery system 250 and target material emitter 30.

In a target material transfer system, the valves may be beneficially realized as so-called freezes valves. FIG. 3 shows a typical freeze valve 300. The valve includes a valve body 310. High pressure molten target material is present at both ends of the freeze valve 300. Freeze valve 300 is shown in its closed state in which target material has been permitted to solidify as a solid target material mass 320 within the valve body 310. This in essence forms a plug that prevents the molten target material 330 and 340 from flowing through the valve 300. When it is desired to permit molten target material to again flow through the valve 300, heat is applied to melt the solid target material mass 320.

Also as mentioned, the thermal mass of the freeze valve 300 that needs to be heated and cooled to operate the freeze valve 300, especially in high pressure applications with thick walled tubing, does not allow for a quick change of the state of the freeze valve 300. Also, high pressure applications typically necessitate greater wall thicknesses thereby increasing the thermal mass of the valve body 310 and so the time required to cycle the freeze valve 300. Also, thermal management of a freeze valve is compromised when neighboring components which are heated or cooled are close by.

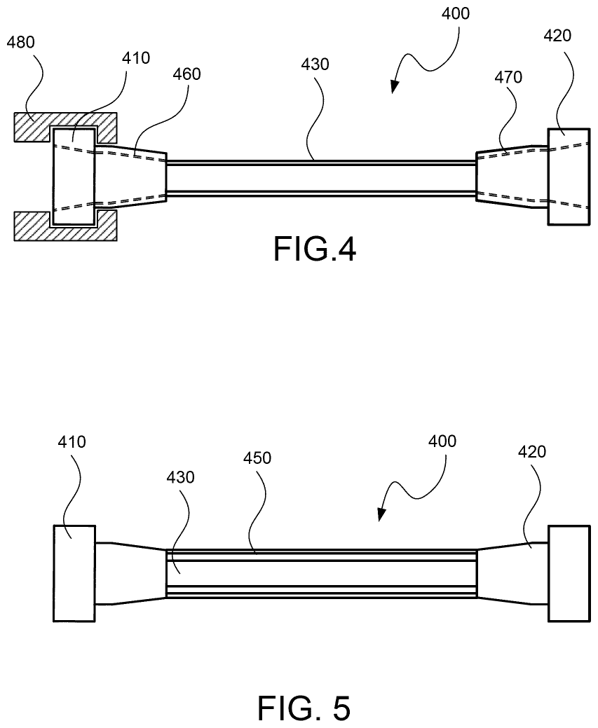

These issues can be ameliorated or avoided by making components such as a the freeze valve partially out of a glass-like material. Such a freeze valve/transfer line is shown in FIG. 4. Component 400 includes a first fitting 410 and a second fitting 420 with a glass tube or capillary 430 extending between them. The glass tube 430 extends into a through bore or channel 460 extending through the first fitting 410 and into another channel or through bore 470 extending through the second fitting 420. The glass tube 430 is sealed to the interior surfaces of the channel 460 inside the first fitting 410 using a glass-to-metal seal as described below. The glass tube 430 is sealed to the interior surfaces of the channel 470 inside the second fitting 420 using a glass-to-metal seal as described below. FIG. 4 also shows a simplified version of a connector 480 which would be used to secure the first fitting 410 or second fitting 420 to another component such as a reservoir or nozzle. One of ordinary skill will appreciate that these connectors can be in any of many forms and composed of any of many materials being selected based on the technical considerations of a particular application.

The glass tube 430 may comprise, for example, a borosilicate glass or an aluminosilicate glass such as Schott 8252 from Schott AG in Mainz, Germany. These glasses may be made to have very low coefficients of thermal expansion making them more resistant to thermal shock. Aluminosilicate glasses can be formulated to tolerate temperatures up to 800° C. (1,470° F.). Their formulations can also be made to have thermal expansion coefficients matching the thermal expansion coefficients of metals used to make the fittings, e.g., molybdenum, making possible the creation of extremely tight and stable gas-proof glass-to-metal seals.

The glass tube 430 may comprise, for example, quartz, soda-lime glass, or alkali barium glass. The glass tube 430 may comprise an alkali barium aluminoborosilicate glass. The glass tube 430 may be optimized or modified, such as by mixing of alkali (Na and K) and/or alkaline earth (Ca and Mg), or the like, to achieve any required physico-chemical properties.

The fittings 410 and 420 may be formed of molybdenum, tantalum and/or tungsten, for example. In some embodiments, the fittings may comprise, for example, aluminum and/or platinum. In some embodiments, the fittings may comprise a metal alloy, such as stainless steel or the like. In some applications the fitting 410 and 420 are made of the same metals or alloys. In other applications the fitting 410 and 420 are made of different metals or alloys.

The durability of the glass tube 430 can be enhanced by providing the outer surface of the glass tube 430 with metal cladding 450 as shown in FIG. 5. The metal cladding 450 may be made, for example, out of nickel or a nickel alloy. The metal cladding may be placed around the glass tube 430 after fabrication of the component. It should be thick enough to protect and add mechanical rigidity to the glass tube 430. This cladding layer may be used in conjunction with any of the embodiments described herein, although the cladding may have to be modified for embodiments in which optical or electrical methods are used to determine whether there is any target material in the glass tube.

Thus, according to an aspect of an embodiment, the target material transfer line/freeze valve hardware includes a glass capillary (tube) with metal fittings at both ends to connect to adjacent target material conveying components. In an embodiment one end of the glass capillary is bonded to a metal fitting using a process such as that described below to create a glass-to-metal seal. After making the seal at one end of the glass tube, another fitting is attached at the other end of the glass tube. The capillary may be temporarily closed at the end of the capillary having the first seal to enable pressurization of the glass capillary when the second seal is made. Alternatively, the seals can be formed at the same time. This is described in greater detail below.

The component 50 may serve as a target material transfer line used to convey target material from one location to another. As described below, the glass tube may be drawn to decrease its diameter thus permitting the fabrication of a flow restrictor. The glass tube may be drawn to decrease its diameter to the extent that it is flexible, thus permitting the fabrication a flexible target material transfer line.

The component 50 may also be implemented as a freeze valve. Making the thermal switching portion of the freeze valves from glass makes it possible to realize a much faster switching or cycle time (time from open to closed or closed to open), with switching times on the order of seconds rather than minutes. The use of a glass tube also simplifies thermal design because it provides improved thermal insulation of the freeze valve from any nearby heated system components.

Also, using freeze valves made partially of glass have the potential to provide many additional benefits due to their faster freeze and thaw times. For example, target material reservoirs can be filled faster and at a higher frequency, so the reservoir volume or capacity can be greatly reduced. Using smaller reservoir volumes creates less risk because there is less stored energy. Using smaller reservoir volumes also makes it possible to reduce energy consumption for heating, reducing the CO₂ footprint of the system.

The freeze valve may be constructed with an extremely small inner diameter, making it possible for the freeze valve to provide additional functionality as a flow restrictor. Also, a target material transfer system using such freeze valves could be fabricated to have a smaller footprint.

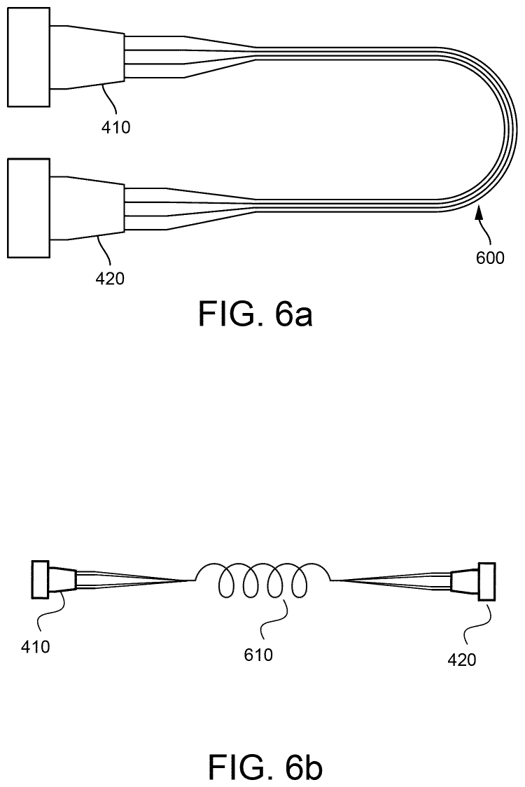

The glass target material transfer line/freeze valve can easily be drawn to make a flexible line. In other words, another target material transfer line component that may be derived from the above is a target material transfer line which is flexible with a reduced diameter. This component can be fabricated by making the target material transfer line as described herein and then drawing the glass tube/capillary so that a portion of the tube between its ends becomes elongated and thinner. Such a target material transfer line is shown in FIG. 6a. This elongated, thinner portion is flexible and may include a bent portion 600 with a bend radius, for example, of approximately 30 mm. Other shapes such as a coil/helix 610 can be formed to increase the functional length of the switching section. This is shown in FIG. 6b. The configuration of FIG. 6b increases the achievable pressure differential across the freeze valve, without significantly increasing freeze/melt time.

This flexible target material transfer line configuration offers further advantages. For example, the flexibility of the target material transfer line reduces or even avoids stress on connected parts and fittings caused by thermal expansion/contraction of the target material transfer line. Also, when used to implement a freeze valve, the thermal mass of a frozen section is significantly reduced, allowing for even faster freezing/melting. The inner diameter may be made smaller than what is achievable in conventional molybdenum machining.

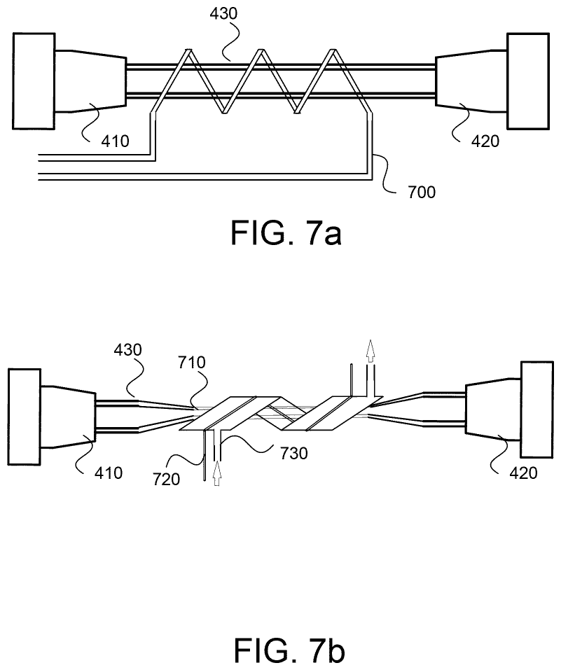

For a freeze valve configuration, it is necessary to heat the switching portion of the valve to maintain the valve in an open state or to switch the valve from a closed state to an open state. This heating can be accomplished in any one or combination of ways. For example, in an embodiment the heating may be accomplished using electrical resistance heaters, with a flexible heater sock 700 with resistive heaters being placed around the capillary 430 of the freeze valve as shown in FIG. 7a.

As another example, an induction coil 720 may be used to couple energy directly into the target material mass inside of the capillary. Such a configuration is shown in FIG. 7b in which the freeze valve has a necked-down central portion 710. Using an induction heater to heat the freeze valve requires less energy because an induction heater specifically heats all metallic freeze valve materials inside the heater coil and the target material inside.

In the embodiment of FIG. 7b the coil 720 is electrically insulated and in contact with the outer diameter of the capillary 430. The inductive energy transfer from the coil 720 to metallic freeze valve components and target material in the glass capillary 430 enables very fast heating. Because the switching section of the freeze valve is made from glass, heating with an induction heater would be very fast as the induction heater's power would be transferred only into the target material. The coil 720 may be cooled using a cooling jacket 730 and mechanical contact between the cooled coil and the freeze valve will enable fast cooling. To the extent a contacting cold coil would reduce heating efficiency, optimization of the conductive and possibly convective heat transfer between coil 720 and the glass capillary 430 could provide benefits for some implementations.

In an embodiment, cooling is accomplished using the cooling fluid in the cooling jacket 730. The freeze valve can be in mechanical contact with the coil 720 if electrical insulation is provided between coil 720 and any metallic portions of the freeze valve. Heat transfer from cooling fluid is generally fast, making it possible to avoid the use of additional elements such as fans and cooling fins, thus making it possible to simplify the system. Also, the fluid cooling requires no moving parts, making it possible to improve the overall reliability of the system. The cooling fluid may be water, or it may be a fluid with a boiling point exceeding the boiling point of water. The cooling system including the cooling jacket 730 may be pressurized to limit the formation of vapor.

The functioning of the freeze valve depends on target material being in the valve. If there is no target material in the valve, the valve cannot close, potentially causing a malfunction of the system and posing a risk of damage or injury. When the freeze valve is made of an opaque, electrically-conductive material the is no simple way to determine if the freeze valve is filled with tin. For some implementations it would be advantageous if the presence or absence of target material in the freeze valve could be easily determined or confirmed. Making the switching portion of the freeze valve from a transparent glass makes it possible to obtain an optical determination of whether the freeze valve contains target material and whether the target material in the freeze valve is liquid or solid. Making the switching portion of the freeze valve from a nonconductive material such as glass makes it possible to obtain an electrical or capacitive determination of whether the freeze valve contains tin.

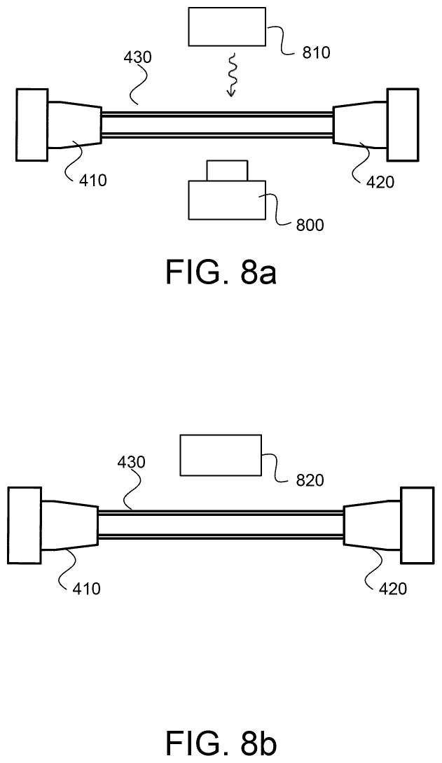

As shown in FIG. 8a, a light source 800 may be placed on one side of the switching portion of the capillary 430 and a sensor 810 may be placed on the other side of the switching portion of the capillary 430. When there is target material in switching portion of the capillary 430 then light from the light source 80 cannot pass through to the sensor 810, thus providing an indication that target material is present in the switching portion of the capillary 430. When there is not any target material in the switching portion of the capillary 430 then light from the light source 80 is able to pass through to the sensor 82 providing an indication that no target material is present in the switching portion of the capillary 430.

Making the switching portion of the freeze valve from a nonconductive material such as glass makes it possible to obtain an electrical, e.g., inductive or capacitive, determination of whether the freeze valve contains target material. As shown in FIG. 8b, a sensor 820 may use electromagnetic induction to detect target material in the switching portion of the capillary 430. A sensor 820 using electromagnetic induction develops a magnetic field which couples with target material in the switching portion of the capillary 430. As another example, the sensor 820 may operate based on capacitive coupling to detect target material by capacitively coupling with target material in the switching portion of the capillary 430. Such an electrical determination could also determine whether the target material is solid or liquid by, for example, detecting an interface of liquid/solid target material. Methods other than optical methods may be used to determine whether target material has sealed a freeze valve. Detection of slight changes in inductance may be used to the extent the target material behaves like an iron core. Also, detection of a change in conductance may be used if the freeze valve has electrically insulated contacts at either end or wires inside the nonconductive tube.

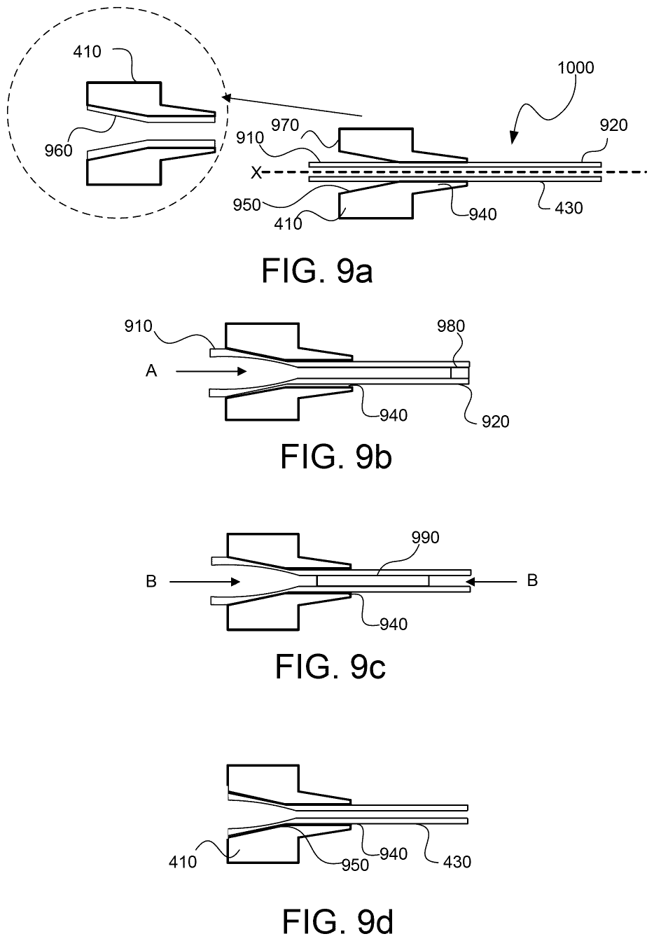

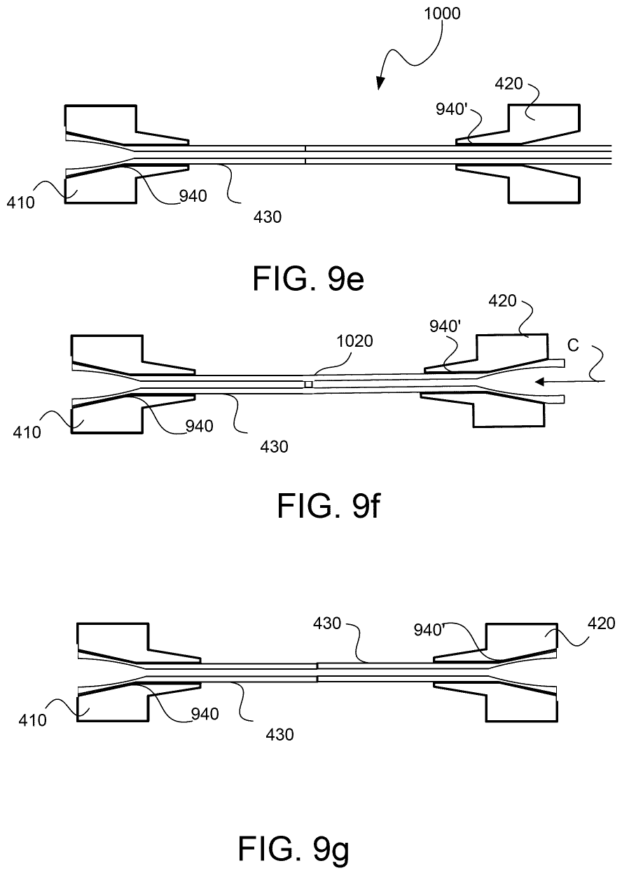

As mentioned, the capillary is sealed to the metallic fitting with a glass-to-metal seal. FIGS. 9a-9g show steps in a process for making a target material transfer line component having such seals. FIG. 9a shows a glass tube 430. The glass tube 430 is a hollow glass tube, open at a first end 910 and at a second end 920. The glass tube 430 may be a straight tube with constant inner and outer diameters, when disposed in metal fitting 410 which corresponds to the fittings as shown, for example, in FIG. 4.

The metal fitting 410 includes a through bore or channel 940. The metal fitting 410 may be formed of molybdenum, tantalum and/or tungsten, for example. In some embodiments, the metal fitting 410 may comprise, for example, aluminum and/or platinum. In some embodiments, the metal fitting 410 may comprise a metal alloy, such as stainless steel or the like.

In the example embodiment of FIG. 9a, a portion 950 of the channel 940 is substantially frustum-shaped. That is, the portion 950 has a substantially conical-shaped surface. Such a frustum/conical shape may be, for example, formed by machining the metal fitting 410 with a conical reamer. In other embodiments, the entire channel may be substantially frustum-shaped. In still other embodiments, the entire channel 940 may be cylindrical. It will also be appreciated that in alternative embodiments falling within the scope of the present invention, the channel may be straight, or substantially straight. That is, in alternative embodiments all, or substantially all, of the channel 940 may be straight, e.g., uniformly cylindrical. The shape of the channel 940 may include a uniformly cylindrical section and a frustum-shaped section.

In one advantageous embodiment, an angle of the sidewalls of the portion 950 of the channel 940 that is substantially frustum-shaped may be between approximately 2 and 5 degrees relative to a longitudinal axis X defined by a center of the channel 940. Note that, for purposes of example only, the angle has been exaggerated in FIGS. 9a-g, which are not drawn to scale. In other embodiments falling within the scope of the present invention, the angle of sidewalls of the portion 950 of the channel 940 that is substantially frustum-shaped may be between greater than 5 degrees or less than 2 degrees relative to the longitudinal axis X defined by the center of the channel 940.

As shown in the inset in FIG. 9a, at least a portion of the metal fitting 410 may advantageously comprise an oxide layer 960 (exaggerated in the inset) on the surface that forms the channel 940, and in particular the portion 950 of the channel 940 that is substantially frustum-shaped may comprise an oxide layer. Such an oxide layer 960 may provide a more robust and/or reliable and/or effective glass-to-metal seal. Beneficially, the provision of an oxide layer, e.g., a metal-oxide layer, provides oxygen atoms that may be used to form an effective glass-to-metal bond layer.

It will be appreciated that the provision of a metal-oxide layer is applicable to any metal used to form a glass-to-metal seal. For example, a metal fitting 410 comprising any of molybdenum, tungsten, tantalum, and/or a metal alloys such as a nickel-cobalt ferrous alloy, may comprise a metal oxide layer. In some example embodiments, at least a portion of the metal fitting 410, e.g., at least a portion of the channel of the metal fitting, may be oxidized to ensure an adequate and/or sufficient oxide layer 960 is present prior to forming the glass-to-metal seal.

Should such an oxide layer be desired but found to be initially absent, or insufficient, the metal fitting 410 may be treated to form an oxide layer. For example, the metal fitting 410 may be heated in the presence of oxygen to accelerate formation of such an oxide layer.

A first step in the method of manufacturing a component for a target material transfer system may comprise disposing the glass tube 430 in the channel 940 of the metal fitting 410.

In FIG. 9a, the first end 910 of the glass tube 430 is shown extending past the end of the metal fitting 410. In other embodiments, the first end 910 of the glass tube 430 may be substantially flush with an end 970 or face of the metal fitting 410. It can be noted that, prior to the heating steps described below, glass tube 430 does not have the same shape as the channel 940 including portion 950. Rather glass tube 430 is straight with a constant outer diameter and does not conform to the shape of portion 950 or channel 940 prior to heating, as shown in FIG. 9a.

An outer diameter of the glass tube 430 is slightly smaller than an internal diameter of the channel 940 in various embodiments. As such, the glass tube 430 can be inserted into the channel 940. For example, a difference between the outer diameter of the glass tube 430 and the internal diameter of the channel 940 may be in the range of 1 mm, 0.1 mm, or less but other differences in the respective diameters may be used in other embodiments.

A further step for manufacturing the component 1000 for a droplet generator may comprise heating the metal fitting 410 or heating the metal fitting 410 and the glass tube 430. Heating of the metal fitting 410 and the glass tube 430 may comprise disposing the metal fitting 410 and the glass tube 430 in a temperature controlled oven or chamber. Heating the metal fitting 410 may comprise induction heating the metal fitting 410. When heating the metal fitting 410 by means of induction, the glass capillary is in turn heated by the metal fitting 410.

The heating process, along with the application of pressure as described below, causes the glass tube 430 to conform to the shape of channel 940, including portion 950.

In one particular embodiment, the metal fitting 410 may be heated in a relatively inert atmosphere. For example, the metal fitting 410 may be disposed within a shroud, vessel, chamber, enclosure, or the like, and exposed to a relatively inert gas such as nitrogen or argon. Beneficially, such a relatively inert gas may prevent oxidation of one or more surfaces of the glass tube 430 or metal fitting 410. For example, a metal fitting 410 comprising molybdenum may be particularly subject to oxidation when heated in the presence of oxygen. Thus, heating the metal fitting 410 in the presence of a relatively inert gas may prevent, or at least minimize, such oxidation on a surface of the metal fitting 410 and/or glass tube 430 in applications in which an oxide layer is undesired. For example, it may be desirable to have an oxide layer present only on a portion of a surface of the metal fitting 410 that forms the glass-to-metal seal.

The inert atmosphere may be provided as a gas flow. As such, a temperature of the atmosphere may be controlled. A temperature of the atmosphere may be controlled or maintained at a relatively constant level. Beneficially, by providing the inert atmosphere as a gas flow, heating of the inert atmosphere may be minimized Beneficially, the gas flow may have a cooling effect on portions of the glass tube 430 exposed to the gas flow. Thus, unwanted deformation of one or more portions of the glass tube 430 that extend or protrude from the metal fitting 410 may be limited.

In yet a further embodiment, the metal fitting 410 may be heated in a relative vacuum environment, e.g., a low-pressure environment. For example, the metal fitting 410 may be disposed within a shroud, vessel, chamber, enclosure, or the like, and a surrounding gas, such as air, may be expelled or otherwise pumped or caused to flow from the shroud, vessel, chamber, or enclosure to achieve a relative vacuum, e.g., a partial vacuum or a low-pressure environment. Beneficially, a relative vacuum, e.g., a partial vacuum or a low-pressure environment, may prevent oxidation of one or more surfaces of the glass tube 430 or metal fitting 410. For example, a metal fitting 410 comprising molybdenum may be particularly subject to oxidation when heated in the presence of oxygen. Thus, heating the metal fitting 410 in a relative vacuum or a low-pressure environment may prevent, or at least minimize, such oxidation.

The heating, and pressurization described below, causes the glass tube 430 to expand within the metal fitting 410 to conform with the shape of channel 940 of the metal fitting. It will be noted that a portion of the glass tube 430 that expands within the metal fitting 410 comprises a thinner sidewall than portions of the glass tube 430 that may be exposed to the gas flow. Beneficially, such a gas flow may ensure that a thickness of the sidewall of portions of the glass tube 430 that may be exposed to the gas flow is maintained at a desired magnitude, and not subject to unwanted deformation, such as expansion, which may thin the sidewall of the glass tube 430.

In one embodiment, a gas flow of argon of between 4 and 8 standard liters per minute is provided, but other gases and gas flows are used in other embodiments.

The glass tube 430 may also be directly heated, e.g., concurrently with heating the metal fitting, such as by temperature controlled oven or chamber. Alternatively (or additionally) the glass tube 430 may be heated by heat transfer from the metal fitting 410 as described above.

By heating the metal fitting 410, the glass tube 430 may be heated to a level where the glass tube 430 becomes soft. That is, the glass tube 430 may become heated to a level whereby the glass tube 430 transitions from a rigid state to a softened state, e.g., a relatively pliable or partially melted state. That is, the glass tube 430 may be heated, either directly or by the metal fitting 410, until a viscosity of the glass that forms the glass tube 430 is reduced to an extent that the glass becomes relatively pliable.

The metal fitting 410 may be heated to a temperature in the range of 800 K to 2000 K. A temperature to which the metal fitting 410 may be heated may depend upon a material used for the glass tube 430. For example, a temperature in the region of 1800 K may be required for a glass tube 430 comprising quartz and a temperature in the region of 800 K may be required for a glass tube 430 comprising a borosilicate glass.

The metal fitting 410 may be heated to at least a working temperature of the glass tube 430, e.g., a temperature at which the glass tube 430 becomes pliable. Preferably, the metal fitting 410 is not heated to a temperature that would cause the glass tube 430 or the metal fitting 410 to deform excessively under its own weight.

A further step for manufacturing a component for a target material transfer system may comprise applying an internal or external pressure to the glass tube 430 such that the outer periphery of the glass tube 430 more completely conforms to the shape of the opposed interior surfaces of the channel 940 and forms a direct glass-to-metal seal with the channel 940, as will be described with reference to FIG. 9b and FIG. 9c. Note that these steps may be performed in reverse order such that pressure is applied before heating. The same is true of the procedure for attaching a metal fitting to the other end of the capillary.

FIG. 9b depicts an internal pressure being applied to the glass tube 430. The step of applying the internal pressure to the glass tube 430 may comprise a step of sealing a first opening 910 or a second opening 920 of the glass tube 430. In the illustrated embodiment of FIG. 9b, the second opening 920 is sealed with cap 980.

The step of sealing the first or second opening 910, 920 may be performed before or after the step of heating the metal fitting 410. For example, after the metal fitting 410 is heated such that the glass tube 430 is softened, the first or second opening 910, 920 may be sealed by compressing, e.g., pinching or crimping, a portion of the glass tube 430 at the first or second opening 910, 920. Of course, such a pinching or crimping would have to be removed before attaching a metal fitting to the other end of the glass tube 430. Furthermore, the step of sealing the first or second opening 910, 920 may be performed before or after the step of disposing the glass tube 430 in the channel 950, 940 of the metal fitting 410.

The first or second opening 910, 920 may be sealed by, for example, a stopper, lid, or cap. Additionally or alternatively, the first or second opening 910, 920 may be sealed by, for example, a glue or resin, such as a curable resin, or the like.

The step of applying the internal pressure to the glass tube 430 may also comprise pumping a gas into the other of the first or second opening 910, 920 of the glass tube 430. That is, if the first opening 910 is sealed, the gas may be pumped into the second opening 920. Conversely if the second opening 920 is sealed, the gas may be pumped into the first opening 910. Preferably, the gas is a relatively inert gas (relative to materials used to make the metal fitting 410 and the glass tube 430), such as nitrogen and/or argon.

The internal pressure may be applied during and/or after heating the metal fitting 410 and the glass tube 430.

For purposes of example only, FIG. 9b shows a cap 250 sealing the second end 920 of the glass tube 430. In the example of FIG. 9b, the gas is pumped into the first end 910 of the glass capillary, in a direction shown by arrow A.

A pump, or compressor, may be communicably coupled to the glass tube 430 to pump the gas into the first end 910 of the glass capillary. For example, as shown in FIG. 9b, a portion of the glass capillary protrudes from, e.g., extends outwardly from, the end 970 or face of the metal fitting 410. As such, a hose or pipe (not shown) may be attached to the protruding portion of the glass tube 430 using any suitable means to form a seal between the hose or pipe and the glass tube 430. The pump, or compressor, may be communicably coupled to the hose or pipe, and therefore configured to apply an internal pressure to the glass tube 430.

As the gas is pumped into the glass tube 430, a pressure within the glass tube 430 increases. In one embodiment, a pressure within the glass tube 430 may be set to approximately 0.5 bar but in other embodiments, a pressure within the glass tube 430 may be set or increased to between 0.1 bar and 10 bar, or higher.

Note that it is also possible to close both ends of the glass tube 430 and use an increase in internal pressure in the glass tube 430 caused by heating to generate the deforming force inside the glass tube 430.

In the example of FIG. 9c, pressure is applied to the ends 910, 920 of the glass tube 430 in the directions shown by arrows B. That is, the directions shown by arrows B are generally opposing. As such, the forces are compressive forces, which act to compress the glass tube 430.

Due to the applied external pressure and the relative pliability of the glass tube 430, which is due to heating of the metal fitting 410 and/or the glass tube 430, the glass tube 430 expands and/or deforms within the channel 950, 940 of the metal fitting 410 until it contacts and conforms to the channel 940 of the metal fitting 410. In particular, and as shown in FIG. 9c, the glass tube 430 expands and/or deforms within the frustum-shaped portion 950 of the channel until it contacts the frustum-shaped portion 950 of the channel of the metal fitting 410. As such, the glass tube 430 expands and/or deforms such that the glass capillary conforms to the shape of the channel 940, and in particular the frustum-shaped portion 950 of the channel.

As previously described, the channel 940 may be straight, or substantially straight, e.g., the channel 940 may not have a frustum-shaped portion. That is, in alternative embodiments all, or substantially all, of the channel 940 may be straight, e.g., uniformly cylindrical. In such embodiments, due to the applied external pressure and to the relative pliability of the glass tube 430, which is due to heating of the metal fitting 410 and/or the glass tube 430, the straight glass tube 430 may expand and/or deform within the channel 940, 950 of the metal fitting 410 until it contacts the channel of the metal fitting 410.

Furthermore, due to the applied external pressure, the temperature of the metal fitting 410, and the temperature of the glass tube 430, a glass-to-metal seal is formed between the glass tube 430 and the metal fitting 410.

As shown in FIG. 9c, the opposing compressive forces shown by arrows B are applied in a longitudinal direction relative to the glass tube 430. Such external forces may be applied by any appropriate means, such as by disposing the glass tube 430 in a machine press. Such a machine press may be mechanical, hydraulic, or pneumatic. Such external forces may be applied by disposing the glass tube 430 between intermediate members, such as plates, and subsequently applying the external pressure to the intermediate members. Such external forces may be applied by gripping one or more portions of the glass capillary 900, such as by one or more clamps or the like, and moving the one or more clamps relative to the metal fitting 410.

The step of applying the external pressure to the glass tube 430 may also comprise inserting a rigid element 990, such as a mandrel, into the glass tube 430 before applying the external pressure. Such a rigid element 990 may prevent the glass tube 430 from collapsing or excessively deforming in an unwanted direction due to the applied external forces.

FIG. 9d depicts a partially formed component manufactured by a method according to an embodiment of the present invention. In contrast to FIGS. 9b and 9c, the portion of the glass tube 430 that protrudes from, e.g., stands proud of, the end 970 or face of the metal fitting 410 has been removed. Removal of the portion may comprise at least one of sanding, grinding, polishing, and/or cutting. In other embodiments, the portion of the glass tube 430 that protrudes from the end 970 or face of the metal fitting 410 may be left in situ, and/or formed into a rim.

A further step in the method of manufacturing the component may comprise cooling the metal fitting 410. Such cooling may be active cooling, e.g., by refrigeration or by means of a cooled gas flow, or by natural cooling, e.g., leaving the metal fitting 410 to come to thermal equilibrium with an ambient temperature. Such cooling may follow or adhere to a pre-defined temperature profile, that is, temperature as a function of time. Beneficially, such cooling may at least partially anneal the glass capillary, thus reducing internal stresses within the glass capillary.

Furthermore, an end of the glass capillary (e.g., after removal of the abovementioned protruding portion) and/or the end 970 or face of the metal fitting 410 may be ground and/or polished. Such grinding and/or polishing may provide a smooth surface, such that an end of the glass tube 430 is flush with the end 970 or face of the metal fitting 410. Furthermore, such grinding or polishing may remove unwanted debris or oxide layers. In particular, for a metal fitting 410 comprising molybdenum, a molybdenum oxide layer may have formed on the end 970 or face of the metal fitting 410. Such polishing and/or grinding may remove such an oxide layer.

A next step in the method of manufacturing a component for a target material transfer system may comprise disposing the other end of the glass tube 430 in the channel 940′ of a second metal fitting 420 as shown in FIG. 9e. The process used to shape the other end of the glass tube 430 essentially mirrors the process used to shape the first end of the glass tube 430. Thus, the description of the process used to shape the first end of the glass capillary applies to the process used to shape the other end of the glass capillary with straightforward adaptations and will not be repeated in the same detail here.

To recapitulate in a summary fashion, essentially, the glass tube 430 is inserted into the channel 940′. A further step for manufacturing the component 1000 may comprise heating the metal fitting 420 or heating the metal fitting 420 and the glass tube 430. Heating of the metal fitting 420 and the glass tube 430 may comprise disposing the metal fitting 420 and the glass tube 430 in a temperature controlled oven or chamber. Heating the metal fitting 420 may comprise induction heating the metal fitting 420. By heating the metal fitting 420 by means of induction, the glass capillary may be heated by the metal fitting 420. The heating process, along with the application of pressure as described below, causes the glass tube 430 to conform to the shape of channel 940′.

The heating, and pressurization described below, causes the glass tube 430 to expand within the metal fitting 420 to conform with the shape of channel 940′ of the metal fitting 420. In other words, heating the metal fitting 420 causes the glass tube 430 to be heated to a level where the glass tube 430 becomes soft.

A further step for manufacturing a component for a target material transfer system may comprise applying an internal or external pressure to the glass tube 430 as shown in FIG. 9f such that the outer periphery of the glass tube 430 conforms to the shape of the opposed interior surfaces of the channel 940′ and forms a direct glass-to-metal seal with the channel 940′, as described with reference to FIG. 9b.

FIG. 9f depicts an internal pressure being applied to the glass tube 430. The step of applying the internal pressure to the glass tube 430 may comprise a step of sealing or otherwise obstructing flow through the glass tube 430. In the illustrated embodiment of FIG. 9f, the glass tube 430 may be blocked with a removable obstruction 1020. The step of blocking the glass tube 430 may be performed before or after the step of heating the metal fitting 420. Furthermore, the step of blocking the glass tube 430 may be performed before or after the step of disposing the glass tube 430 in the channel 940′ of the metal fitting 410. The glass tube 430 may be sealed by, for example, a stopper, lid, or cap. Additionally or alternatively, the glass tube 430 may be sealed by, for example, a glue or resin, such as a curable resin, or the like.

The step of applying the internal pressure to the glass tube 430 may also comprise pumping a gas into the other of second opening of the glass tube 430. The internal pressure may be applied during and/or after heating the metal fitting 410 and the glass tube 430.

For purposes of example only, FIG. 9e shows an obstruction 1020 sealing the glass tube 430. In the example of FIG. 9e, the gas is pumped into the second end of the glass tube 430, in a direction shown by arrow C.

As the gas is pumped into the glass tube 430, a pressure within the glass tube 430 increases. Due to the applied internal pressure and to the relative pliability of the glass tube 430, which is due to heating of the metal fitting 420 and/or the glass tube 430, the glass tube 430 expands and/or deforms within the channel 940′ of the metal fitting 420 until it contacts the inner surfaces of the channel 940′ of the metal fitting 420. In particular, and as shown in FIG. 9e, the glass tube 430 expands and/or deforms within the frustum-shaped portion of the channel 940′ until it contacts the frustum-shaped portion of the channel 940′ of the metal fitting 420. As such, the glass tube 430 expands and/or deforms such that the glass tube 430 conforms to the shape of surfaces of the channel 940′, and in particular the frustum-shaped portion of the channel 940′.

Furthermore, due to the pressure applied by the gas, the temperature of the metal fitting, and the temperature of the glass tube 430, a glass-to-metal seal is formed between the glass tube 430 and the metal fitting. After glass-to-metal seal has been formed, the obstruction 1020 may be removed.

Also an external pressure may be applied to the glass tube 430. The step of applying the external pressure to the glass tube 430 may comprise applying opposing compressive forces to at least one of: portions of the glass tube 430 extending from the channel; and/or ends of the glass capillary similarly as to what has been shown and described in connection with FIG. 9c.

The external pressure may be applied during and/or after heating the metal fitting and the glass tube 430.

FIG. 9g depicts a fully formed component manufactured by a method according to an embodiment of the present invention. The portion of the glass tube 430 that protrudes from the left end or face of the metal fitting 420 has been removed. Removal of the portion may comprise at least one of sanding, grinding, polishing, and/or cutting. In other embodiments, the portion of the glass tube 430 that protrudes from the end or face of the metal fitting 420 may be left in situ, and/or formed into a rim.

The above describes a process in which first one side of the component is fabricated and then the other. It will be apparent, however, that some of the above steps such as heating and the application of pressure could be performed at substantially the same time as described below.

Also, the process may include a next step of heating the glass tube 430 to the point when it can be stretched. This step could also be simply maintaining the glass tube 430 at the temperature where it may be stretched and deformed. Stretching narrows the middle portion of the glass tube 430 so that it resembles the configuration of FIG. 7b or with even more elongation the configuration of FIG. 6a. Sufficient stretching renders the narrowed portion of the glass capillary pliable to it can be formed into various shapes such as the curved portion of FIG. 6a, the helical portion of FIG. 6b, or even an L-shaped right angle configuration.

The method may comprise a step of annealing the glass tube 430 and/or the metal fitting 410. The particular temperatures and/or heating and/or cooling rates required for annealing of the glass tube 430 may depend upon the particular glass type and/or composition of glass. For example, the glass tube 430 may be heated to approximately 600 K to 800 K, before cooling to an ambient temperature, but other temperatures can also be used in other embodiments. Such an annealing step may be repeated one or more times.

The step of annealing the glass tube 430 may be performed before and/or after the step of removing the portion of the glass tube 430 that protrudes from, e.g., stands proud of, the end 970 or face of the metal fitting 410.

Beneficially, the frustum-shaped channel of the example embodiment shown in FIGS. 9a to 9g provides enhanced sealing between the glass tube 430 and the metal fittings 410 and 420 in use. That is, in use a pressure may be applied to an internal surface, e.g., internal sidewall, of the glass tube 430 due to a pressurized target material being entering the glass tube 430 from one end or the other and being ejected or emitted from the glass tube 430 at the other end. Such pressure exerted by the target material may, to some extent, further expand the glass tube 430 thus pressing the glass tube 430 against the metal fittings 410 and 420. Thus, the glass-to-metal seal between the glass tube 430 and the metal fittings 410 and 420 may form, at least to some extent, self-energizing seals, e.g., seals that are improved by the pressure applied to the internal surface of the glass tube 430 in use.

It is advantageous that a coefficient of thermal expansion (CTE) of the metal fitting 410 or 420 is substantially the same as, or within a predefined range relative to, a CTE of the glass tube 430 over an operational temperature range of the component 1000. Furthermore, it is also advantageous that a CTE of the metal fitting 410 and 420 is substantially the same as, or within a predefined range relative to, a CTE of the glass tube 430 over a temperature range which includes temperatures required to form the glass-to-metal seal, e.g., a manufacturing temperature range of the component. That is, the glass-to-metal seal is formed at a temperature wherein the glass becomes soft and is subsequently cooled to room temperature. As such, it is advantageous that a CTE of the metal fitting 410 and 420 is substantially the same as, or within a predefined range relative to, a CTE of the glass tube 430 over an entire temperature range that includes the temperature at which the glass becomes soft and room temperature, and preferably also an operational temperature range of the component 1000, which may comprise temperatures less than room temperature.

For example, a metal fitting comprising molybdenum may have a CTE of approximately 5.5 ppm/K. As such, predefined range for the CTE of a glass capillary may be, for example, +/−0.5 ppm/K. Various borosilicate or aluminosilicate glasses comprise a CTE matched to within +/−0.5 ppm/K to molybdenum. A glass capillary having a CTE lower than that of the metal fitting may be selected to create an interference fit between the metal fitting and the glass capillary. For example, one embodiment may comprise a metal fitting comprising molybdenum and a glass capillary comprising a borosilicate with a CTE of approximately 3.3 ppm/K. Such pressure may beneficially cause the glass-to-metal seal to additionally and/or at least partially, form an interference fit between the metal fitting and the glass capillary. That is, in use a pressure may be applied to an internal surface of the glass tube 430 whereby the pressure may, to some extent, further expand the glass tube 430 thus pressing the glass tube 430 against the metal fitting 410.

The operational temperature range may depend upon the target material emitted or ejected by the component 1000. For example, the operational temperature range for liquid tin as a target material may be approximately 300 K to 530 K.

Furthermore, in use a target material may be, for example a tin compound, e.g., SnBr4, SnBr2, SnH4, or a tin alloy, e.g., tin-gallium alloys, tin-indium alloys, tin-indium-gallium alloys, or a combination thereof. Depending on the material used, the target material may be provided at various temperatures including room temperature or near room temperature (e.g., tin alloys, SnBr4), at an elevated temperature, (e.g., pure tin) or at temperatures below room temperature, (e.g., SnH4). Thus, it is particularly beneficial to form a glass-to-metal seal between the glass tube 430 and the metal fitting 410 and 420 that is relatively temperature invariant in terms of its performance across an entire operational temperature range.

By closely matching a CTE of the glass tube 430 to the CTE of the metal fitting 410 and 420, cracking of the glass capillary after heating-up the component to a working temperature, e.g., 500 to 500 K for molten tin, may be avoided.

Also, during manufacture of the component, and/or in use, if the CTE of the glass tube 430 is higher than that of the metal fitting 410 and 420, then during cooling of the component 1000 the glass tube 430 will contract faster than the metal fitting 410 and 420 contracts. Such a difference in contraction rates between the glass tube 430 and the metal fitting 410 and 420 may be detrimental to the integrity of the glass-to-metal seal. That is, such a difference in contraction rates between the glass tube 430 and the metal fitting 410 and 420 may cause the glass capillary to separate from the metal fitting 410 and 420. Thus, it is beneficial to have the contraction rate of the glass tube 430 be less than or equal to that of the metal fitting 410 and 420.

The term “inert” used throughout this specification should be construed as meaning chemically inert relative to the materials used to make the glass tube 430 and the metal fitting 410 and 420.

The term “glass-to-metal” seal refers to a seal, e.g., a hermetic seal between a glass and a metal, wherein the metal is construed as comprising a metal, a metal alloy, and/or a metal oxide. That is, the term “glass-to-metal seal” should be understood to comprise a seal between a glass and a metal, wherein the metal may comprise an oxide layer. For example, in a particular embodiment of the present invention, wherein the metal fitting comprises molybdenum, the term “glass-to-metal seal” includes a seal between the glass tube 430 and a surface of the metal fitting, wherein prior to the seal being formed a surface of the metal fitting 410 and 420 that is to be sealed to the glass tube 430 may have an oxide layer.

As mentioned, after both metal fittings 410 and 420 have been sealed to the glass tube 430, the capillary may be heated, stretched, and formed into any of the various shapes described above including straight (FIG. 7b) and helical (FIG. 6b). A drawn capillary freeze valve as shown in FIG. 7b may have an inner diameter of only 40 micrometer. That implies that a 50 mm long freeze valve may contain as little as 0.4 micrograms of target material that would need to be heated, combined with the glass near the target material in order to have molten target material in the glass tube 430. The outside of the glass tube 430 may still be cooled. It is expected that this small thermal mass can be heated from 150 to 250° C. within seconds using, for example, 100 watt of induction power. The total time for switching is then approximately 70 s. This is as compared with a conventional freeze valve which has a switching time on the order of 1800 s. Thus, switching time may be reduced.

Embodiments of freeze valves as described herein may be used as any of various valves described in FIG. 2 including primary valve 270, refill valve 280, and service valve 290.

Implementation of the invention may permit the reservoirs 220, 230 (FIG. 2) to be scaled to allow for continuous operation during switching, with an engineering safety factor. This would permit a reduction in the reservoir sizes. The size of an inline refill reservoir, for example, could be reduced from about 400 ml to about 30 ml.

The small volume freeze valve reduces energy consumption/rejection: The thermal mass requiring heating and freezing can be significantly reduced by use of the drawn glass tube shown in FIG. 7b. As an example, comparing the mass and specific heat of a typical freeze valve shown in FIG. 3 with a 5 cm long section of the line shown in FIG. 7b, the energy required to heat the glass line would be calculated to be a small fraction of that required for the standard molybdenum freeze valve. The need for cooling will be reduced by the same factor, enabling the use of much simpler cooling schemes, e.g., compressed air vs. cooling fluid.

The glass freeze valve simplifies system design by enabling closer positioning of heated and cooled zones. It mitigates problems encountered in cooling the freeze valves to the desired temperature due to heat transfer from adjacent parts that need to be kept at elevated temperatures. In current designs these issues are pronounced because of the very high thermal conductivity of the molybdenum used in the system's components, i.e. ˜140 W/(mK). The thermal conductivity of glass is about 1/100th of that, or about 1.4 W/(mK). That means that the heat transfer per unit distance between parts is significantly reduced, allowing for much closer spacing while maintaining or even reducing the heat flux from the hot part to the cold part. As this heat flux is waste, its reduction will also reduce the overall power consumption of the system. Again, this effect would be further enhanced with the minimum volume freeze valve shown in FIG. 7b, as the thin line transfers even less power.

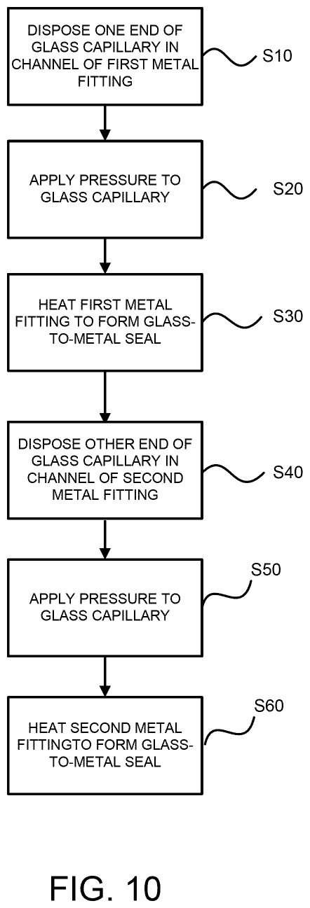

FIG. 10 is a flowchart setting out steps of a method for fabricating a component of a target material transfer system according to an aspect of an embodiment. In a step S10 one end of a glass capillary is disposed in the channel of first metal fitting. In a step S20 pressure is applied to the glass capillary. In a step S30 the first metal fitting is heated by any suitable method, including by an electrical resistive heater or by induction heating, to form a glass-to-metal seal between the glass capillary and the channel in the first metal fitting. Note that these steps S20 and S30 may be performed in the opposite order or at the same time. In a step S40 the other end of the glass capillary is disposed in the channel of a second metal fitting. In a step S50 pressure is applied to the glass capillary. In a step S60 the second metal fitting is heated, again by any suitable method including by an electrical resistive heater or by induction heating, to form a glass-to-metal seal between the glass capillary and the channel in the second metal fitting. Note that these steps S50 and S60 may be performed in the opposite order.

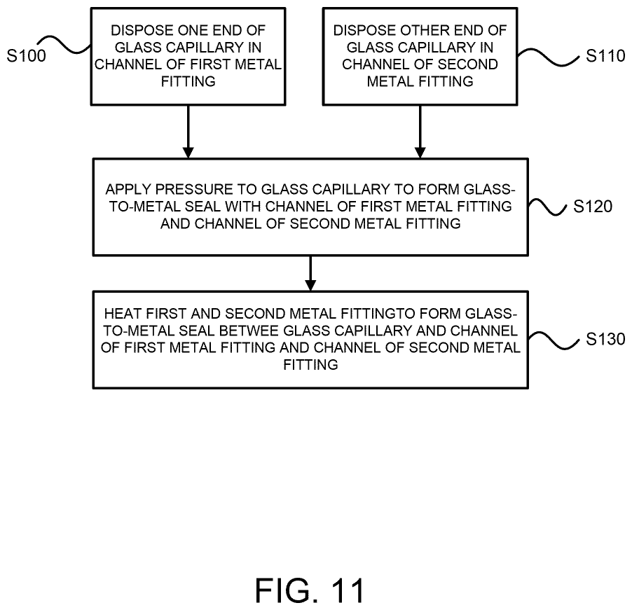

As mentioned, these steps may be performed in the order set forth above or several of the steps may be performed simultaneously as in the procedure described in the flowchart in FIG. 11. There, in a step S100 one end of the glass capillary is disposed in a channel of the first metal fitting. A step S110 of disposing the other end of glass capillary in a channel of second metal fitting is performed subsequently or concurrently with step S100. In a step S120 both the first and second metal fittings are heated by any suitable method including by proximity to an electrical resistive heater or by induction heating. In a step S130 pressure is applied to the glass capillary to form glass-to-metal seals with the channel of first metal fitting and the channel of second metal fitting.

The formation methods disclosed herein avoid the use of welds that are prone to cracking and failure, causing significant machine downtime. The fabrication methods disclosed herein also avoid the cost of manufacturing molybdenum lines.

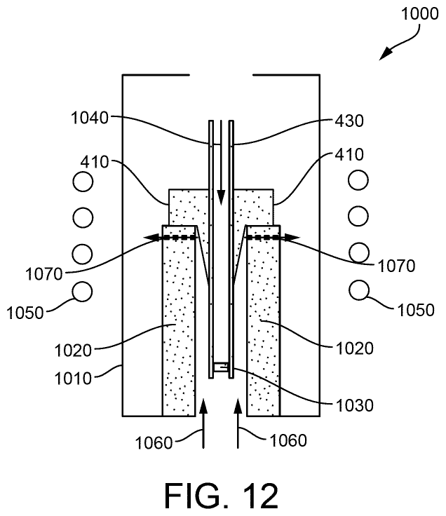

FIG. 12 is a diagram showing more details of fabrication of a target material transfer system component in which gas pressure assists in the formation of a glass-to-metal seal between a glass capillary and a metal fitting. In particular, FIG. 12 shows a fixture 1000 having a partial enclosure 1010 and support 1020. A metal fitting 410 is placed on the support 1020 such that a peripheral shoulder on the metal fitting 410 is supported so that downward movement is constrained. A glass tube 430 is placed in a channel in the metal fitting 410 either before or after the metal fitting 410 is placed in the fixture 1000. A bottom end of the glass tube 430 is closed by a seal 1030. Once the metal fitting 410 is placed in the fixture 1000 a gas indicated by the arrow 1040 is caused to flow into and pressurizing the inside of the glass tube 430, creating a force tending to urge the glass tube 430 into greater contact with the metal fitting 410. At the same time, an inductive heater 1050 is energized, causing the metal fitting 410 to heat up. The metal fitting 410 in turn causes the portion of the glass tube in the metal fitting 410 to become hot and pliable. The combination of the heat and pressure causes the glass-to-metal seal to form. This is a pressure control process with regard to the gas 1040 because the pressure of this gas is controlled to control the amount of force urging the glass tube 430 and the metal fitting together.

During this process it may be desirable to control the temperature of the portion of the glass tube 430 extending out of the fitting 410 (downward in the figure) so that this portion of the glass tube does not deform and maintains its internal diameter. Towards this end a flow of a cooling or protective gas indicated by the arrows 1060 may be introduced which flows past the outside of the glass tube 430 and escapes through vents 1070. Note in this regard that the portion of the metal fitting extending downward past the support 1020 has less mass and so transfers less heat to the portion of the glass tube 430 surrounded by this downward-extending portion.

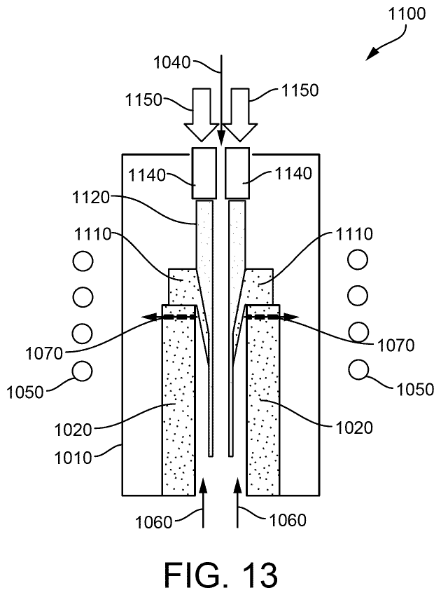

FIG. 13 is a diagram showing more details of fabrication of a target material transfer system component in which mechanical pressure assists in the formation of a glass-to-metal seal between a glass capillary and a metal fitting. In particular, FIG. 13 shows a fixture 1100 having a partial enclosure 1010 and support 1020. A metal fitting 1110 is placed on the support 1020 such that a peripheral shoulder on the metal fitting 410 is supported so that downward movement is constrained. A glass tube 1120 is placed in a channel in the metal fitting 1110 either before or after the metal fitting 1110 is placed in the fixture 1100. Once the metal fitting 410 is placed in the fixture 1100 an actuator 1140 is activated creating a downward force indicated by the arrows 1150 tending to urge the glass tube 1120 into greater contact with the metal fitting 1110. A gas indicated by the arrow 1040 is caused to flow into the glass tube 1120 to assist in maintaining an internal diameter of the glass tube 1120. At the same time, an inductive heater 1050 is energized, causing the metal fitting 1110 to heat up. The metal fitting 1110 in turn causes the portion of the glass tube 1120 in the metal fitting 410 to become hot and pliable. The combination of the heat and pressure causes the glass-to-metal seal to form. This is a flow control process with regard to the gas 1040 because the flow of this gas is controlled to maintain the inner diameter of the glass tube 1120.

It will be noted that the glass tube 1120 is an example of a tube which has a lengthwise variation in wall thickness. While the inner diameter of the glass tube 1120 is substantially constant, the outer diameter varies from a thicker portion to a thinner portion with a transitional portion in between. The channel in the metal fixture 1110 is also provided a contour that matches the contour of the transitional portion. A glass tube 1120 with a varying wall thickness would be useful in application where the thinning of the walls of a glass tube starting with constant wall thickness would unacceptably impair the mechanical strength of the glass tube. In other words, the process of partially extruding the glass tube causes lengthwise portions the walls of the glass tube to thin. Initially providing these portions with more glass makes it possible to preserve a minimum thickness of these portions and so their mechanical strength.

Again, during the fabrication process it may be desirable to control the temperature of the portion of the glass tube 1120 extending out of the fitting 1110 (downward in the figure) so that this portion of the glass tube does not deform and maintains its internal diameter. Towards this end a flow of a cooling or protective gas indicated by the arrows 1060 may be introduced which flows past the outside of the glass tube 1120 and escapes through vents 1070. Note in this regard that the portion of the metal fitting extending downward past the support 1020 has less mass and so transfers less heat to the portion of the glass tube 1120 surrounded by this downward-extending portion.

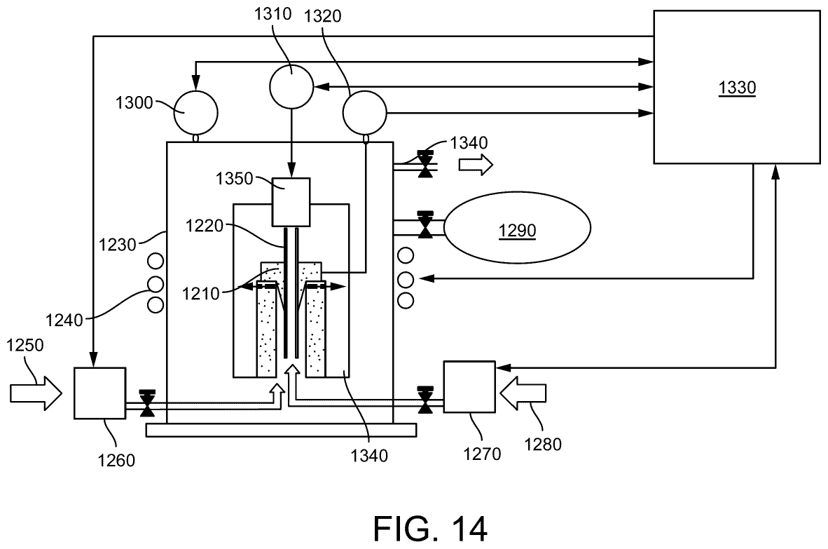

FIG. 14 is a schematic diagram of a system for fabricating a component for a target material transfer system as described above. In FIG. 14, a metal fitting 1210 with a glass capillary 1220 inserted in a channel in the metal fitting 1210 is placed into a fixture 1340 to hold the combination of the metal fitting 1210 and the glass capillary 1220 in a chamber 1230. The metal fitting 1210 is heated by induction using coil 1240. The heating of the metal fitting 1210 in turn heats the glass capillary 1220.

If the bottom of the glass capillary is sealed, the glass capillary 1220 becomes pliable as a pressure differential is created between the inside and outside of the glass capillary 1220, for example, by controlling, e.g., reducing, the pressure in the chamber 1230. Thus, pressure control may be used to create a pneumatic force. A gas flow may be used to ensure that the internal diameter of the glass capillary 1220 stays constant. The system of FIG. 14 also includes a press 1350 which can be used instead pressure control and with flow control to create a force to cause the glass capillary 1210 to deform and form a glass-to-metal seal with the channel surfaces.

The pressure control and/or press 1350 generates a force on the portion of the glass capillary 1220 inside the channel in the metal fitting 1210 causing it to deform and conform to the shape of the channel to form a glass-to-metal seal with the channel surfaces. After this is completed, the other end of the capillary may be inserted into a second metal fitting and the process repeated.

The system depicted in FIG. 14 also includes a mass flow controller 1260 for controlling the flow of a cooling or protective gas which can be an inert gas such as argon around the outside of the glass tube 1220. The system depicted in FIG. 14 also includes a mass flow controller 1270 for controlling the flow of a gas 1280 which can be an inert gas such as argon though the center of the glass tube 1220 to increase the pressure inside the glass tube 1220. The system depicted in FIG. 14 also includes a vacuum source 1290 for selectably applying a vacuum to the interior of the chamber 1920. The system also includes a device 1300 for measuring a vacuum in the chamber, a device 1310 for measuring a force applied to the metal fitting 1210, and a sensor 1320 for measuring the temperature of the metal fitting 1210. The system also includes a controller 1330 which accepts inputs from the sensors and controls the mass flow controllers and the power applied to the inductive coil. The system also includes a vent 1340 for venting the interior of the chamber 1230.

Thus, an apparatus for forming a component for a target material transfer system for a laser-produced plasma radiation source, the apparatus comprising a tool adapted to hold a metal fitting having a glass tube inserted in a channel in the metal fitting, an inductive coil adapted to heat the metal fitting by inductive heating, a gas conduit adapted to apply pneumatic pressure to the fitting and glass tube, and a press adapted to apply a mechanical force to the metal fitting and the glass tube to force the glass tube into contact with the channel.

While specific embodiments of the invention have been described above, it will be appreciated that the invention may be practiced otherwise than as described. The descriptions above are intended to be illustrative, not limiting. Thus, it will be apparent to one skilled in the art that modifications may be made to the invention as described without departing from the scope of the claims set out below.

Thus, while the subject matter disclosed herein has been described in the context of target material transfer lines, freeze valves, and flow restrictors for supplying a droplet generator of an EUV radiation source, it will be apparent that this subject matter may be beneficially applied in other contexts. The disclosed subject matter is therefore not limited in its application to systems for generating EUV radiation. For example, such a component may be generally applicable to any fluid conveyance application, and in particular any fluid conveyance application wherein the fluid to be conveyed is under pressure.

Although specific reference may have been made above to the use of embodiments of the invention in the context of optical lithography, it will be appreciated that the invention, where the context allows, is not limited to optical lithography, and may be used in other applications, for example imprint lithography.

The embodiments can be further described using the following clauses:
1. A component for a target material supply system for an EUV radiation source, the component comprising:
a first fitting made of metal and having a first channel;
a tube member made of glass and having a first end disposed within the first channel and attached to an interior of the first channel by a first glass-to-metal seal; and
a second fitting made of metal having a second channel, the tube member having a second end disposed within the second channel and attached to an interior of the second channel by a second glass-to-metal seal.
2. The component of clause 1 wherein at least one of the interior of the first channel and the interior of the second channel comprises a metal oxide layer which seals to the respective end of the tube member.
3. The component of clause 1 wherein at least one of the first fitting and the second fitting comprises molybdenum or tantalum.
4. The component of clause 1 wherein the tube member comprises borosilicate glass.
5. The component of clause 1 wherein the tube member comprises aluminosilicate glass.
6. The component of clause 1 further comprising an electrically conductive coil disposed around an intermediate longitudinal portion of the tube member.
7. The component of clause 6 wherein the coil is adapted to provide ohmic heating of the tube member and any contents of the tube member.
8. The component of clause 6 wherein the coil is adapted to couple RF energy into any electrically conductive contents of the tube member.
9. The component of clause 6 wherein the coil comprises a jacket adapted to carry a cooling fluid.
10. The component of clause 1 further comprising a metallic cladding layer disposed around the tube member.
11. The component of clause 1 wherein the tube member has a first inner diameter at the first fitting and a second inner diameter smaller than the first inner diameter at a longitudinal section between the first fitting and the second fitting.
12. The component of clause 11 wherein the longitudinal section is straight.
13. The component of clause 11 wherein the longitudinal section is helical.
14. The component of clause 11 wherein the longitudinal section is flexible.
15. The component of clause 1 further comprising an inspection system arranged to inspect the tube member.
16. The component of clause 15 wherein the inspection system comprises a light source arranged to direct light at the tube member and a sensor arranged to receive light from the light source that has passed through the tube member to determine whether an opaque substance is in the tube member.
17. The component of clause 15 wherein the inspection system is arranged to determine by a variation in capacitance whether an electrically conductive substance is within the tube member.
18. The component of clause 15 wherein the inspection system is arranged to determine by a variation in inductance whether an electrically conductive substance is within the tube member.
19. The component of clause 1, wherein the component is in fluid communication with at least one reservoir through the first fitting and in fluid communication with a droplet generator through the second fitting.
20. A method of manufacturing a component for a target material transfer system, the method comprising:
(a) disposing a first end of a glass capillary in a channel of a first metal fitting;
(b) applying a pressure to the glass capillary;
(c) heating the first metal fitting such that the first end of the glass capillary heats and conforms to the shape of, and forms a direct glass-to-metal seal with, an interior surface of the channel of the first metal fitting;
(d) disposing a second end of the glass capillary in a channel of a second metal fitting;
(e) applying a pressure to the glass capillary; and
(f) heating the second metal fitting such that the second end of the glass capillary heats and conforms to the shape of, and forms a direct glass-to-metal seal with, an interior surface of the channel of the second metal fitting.
21. The method of clause 20, wherein the method is performed in an order (a) through (f).
22. The method of clause 20, wherein the method is performed in an order (a), (d), (b), (c) (e) and (f).
23. The method of clause 20, wherein (b) is performed together with (d) and (c) is performed together with (f).
24. The method of clause 20 wherein at least a portion of the channel is frustum-shaped.
25. The method of clause 20, wherein (a) comprises disposing the glass capillary in the form of a tube with a constant diameter and wherein (b) and (c) change the shape of the capillary.
26. The method of any of clauses 20 to 25, wherein (c) comprises applying an internal pressure to the glass capillary by
sealing the second end of the glass capillary, and
pumping a gas into the first end of the glass capillary.
27. The method of any of clauses 20 to 25, wherein (c) comprises applying an external pressure to the glass capillary by applying opposing compressive forces to at least one of:
portions of the glass capillary extending from the channel; and
one or both ends of the glass capillary.
28. The method of clause 27, wherein the opposing compressive forces are applied along a longitudinal direction of the glass capillary.
29. The method of clause 27, further comprising the step of inserting a rigid element into the glass capillary before applying the external pressure.
30. The method of any of clauses 20 to 25, wherein pressure is applied to the glass capillary during and/or after heating the metal fitting.
31. The method of any of clauses 20 to 25, wherein a coefficient of thermal expansion of the glass capillary is less than or equal to a coefficient of thermal expansion of the metal fitting over a temperature range comprising an operational temperature range of the component and a manufacturing temperature range of the component.
32. The method of any of clauses 20 to 25, wherein the metal fitting comprises molybdenum, tantalum, tungsten, or a metal alloy and/or the glass capillary comprises a borosilicate, an aluminosilicate, or quartz.
33. The method of any of clauses 20 to 25, wherein at least a portion of the interior surface of the metal fitting comprises a metal oxide layer with the glass capillary being joined to the metal oxide layer.
34. The method of any of clauses 20 to 25, further comprising annealing the glass capillary and/or the metal fitting after allowing the metal fitting to cool.
35. The method of any of clauses 20 to 25, wherein heating the metal fitting comprises induction heating the first and second metal fittings.
36. The method of clause 35, further comprising providing a flow of an inert gas during the induction heating, the flow directed to the glass capillary.
37. The method of any of clauses 20 to 25, wherein each of the channels is cylindrical.
38. The method of any of clauses 20 to 25, wherein at least one of the step of heating the first metal fitting and the step of heating the second metal fitting comprises heating the metal fitting in an inert atmosphere or a relative vacuum.
39. The method of any of clauses 20 to 25, wherein (a) comprises disposing the glass capillary in the channel of the first metal fitting such that the glass capillary protrudes from both ends of the channel.
40. The method of clause 39, wherein at least one portion of the glass capillary that protrudes from the metal fitting is removed by at least one of: sanding, grinding, polishing, and/or cutting.
41. A method of controlling flow of a target material in a target material transfer system, the method comprising:
providing a freeze valve comprising a first fitting made of metal and having a first channel, a tube member made of glass and having a first end disposed within the first channel and attached to an interior of the first channel by a first glass-to-metal seal, and a second fitting made of metal having a second channel, the tube member having a second end disposed within the second channel and attached to an interior of the second channel by a second glass-to-metal sea;
introducing liquid target material into the tube member;
freezing the target material; and
heating the target material to form a liquid that transfers from at least one reservoir in fluid communication with the freeze valve to a droplet generator in fluid communication with the freeze valve.
42. A component for a target material transfer system for a laser-produced plasma radiation source, the component comprising:
a glass capillary;
a first metal fitting for coupling a first end of the glass capillary to a first portion of the target material transfer system, the first end of the glass capillary being conformed to a shape of a channel of the first metal fitting, and wherein the first end of the glass capillary forms a direct glass-to-metal seal with the channel of the first metal fitting; and
a second metal fitting for coupling a second end of the glass capillary to a second portion of the target material transfer system, the second end of the glass capillary being conformed to a shape of a channel of the second metal fitting, and wherein the second end of the glass capillary forms a direct glass-to-metal seal with the channel of the first metal fitting.
43. The component of clause 42 wherein a first lengthwise portion of the glass capillary has a first wall thickness and wherein a second lengthwise portion of the glass capillary has a second wall thickness different from the first wall thickness.
44. The component of clause 43 wherein the glass capillary comprises a transitional region between the first lengthwise portion and the second lengthwise portion and having a wall thickness varying between the first wall thickness and the second wall thickness.
45. The component of clause 42, wherein the glass capillary comprises a borosilicate, an aluminosilicate, or quartz.
46. The component of clause 42, wherein the shape of the channel in the first metal fitting includes a uniformly cylindrical section and/or a frustum-shaped section.
47. Apparatus for forming a component for a target material transfer system for a laser-produced plasma radiation source, the apparatus comprising:
a tool adapted to hold a metal fitting having a glass tube inserted in a channel in the metal fitting; an inductive coil adapted to heat the metal fitting by inductive heating;
a gas conduit adapted to apply pneumatic pressure to the fitting and glass tube; and
a press adapted to apply a force to the metal fitting and the glass tube to force the glass tube into contact with one or more surfaces of the channel.

Other embodiments and implementations are found within the scope of the following claims.

1. A component for a target material supply system for an EUV radiation source, the component comprising:
a first fitting made of metal and having a first channel;
a tube member made of glass and having a first end disposed within the first channel and attached to an interior of the first channel by a first glass-to-metal seal; and
a second fitting made of metal having a second channel, the tube member having a second end disposed within the second channel and attached to an interior of the second channel by a second glass-to-metal seal.

2. The component of claim 1 wherein at least one of the interior of the first channel and the interior of the second channel comprises a metal oxide layer which seals to the respective end of the tube member.

3. The component of claim 1 wherein at least one of the first fitting and the second fitting comprises molybdenum or tantalum.

4. The component of claim 1 wherein the tube member comprises borosilicate glass or aluminosilicate glass.

5. (canceled)

6. (canceled)

7. The component of claim 1 further comprising an electrically conductive coil disposed around an intermediate longitudinal portion of the tube member and wherein the coil is adapted to provide ohmic heating of the tube member and any contents of the tube member.

8. The component of claim 1 further comprising an electrically conductive coil disposed around an intermediate longitudinal portion of the tube member and wherein the coil is adapted to couple RF energy into any electrically conductive contents of the tube member.

9. The component of claim 8 wherein the coil comprises a jacket adapted to carry a cooling fluid.

10. (canceled)

11. The component of claim 1 wherein the tube member has a first inner diameter at the first fitting and a second inner diameter smaller than the first inner diameter at a longitudinal section between the first fitting and the second fitting.

12.-15. (canceled)

16. The component of claim 1 further comprising an inspection system arranged to inspect the tube member and wherein the inspection system comprises a light source arranged to direct light at the tube member and a sensor arranged to receive light from the light source that has passed through the tube member to determine whether an opaque substance is in the tube member.

17. (canceled)

18. The component of claim 1 further comprising an inspection system arranged to inspect the tube member and wherein the inspection system is arranged to determine by a variation in inductance or capacitance whether an electrically conductive substance is within the tube member.

19. The component of claim 1, wherein the component is in fluid communication with at least one reservoir through the first fitting and in fluid communication with a droplet generator through the second fitting.

20. A method of manufacturing a component for a target material transfer system, the method comprising:
(a) disposing a first end of a glass capillary in a channel of a first metal fitting;
(b) applying a pressure to the glass capillary;
(c) heating the first metal fitting such that the first end of the glass capillary heats and conforms to the shape of, and forms a direct glass-to-metal seal with, an interior surface of the channel of the first metal fitting;
(d) disposing a second end of the glass capillary in a channel of a second metal fitting;
(e) applying a pressure to the glass capillary; and
(f) heating the second metal fitting such that the second end of the glass capillary heats and conforms to the shape of, and forms a direct glass-to-metal seal with, an interior surface of the channel of the second metal fitting.

21.-23. (canceled)

24. The method of claim 20 wherein at least a portion of the channel is frustum-shaped.

25. The method of claim 20, wherein (a) comprises disposing the glass capillary in the form of a tube with a constant diameter and wherein (b) and (c) change the shape of the capillary.

26. The method of claim 20, wherein (c) comprises applying an internal pressure to the glass capillary by
sealing the second end of the glass capillary, and
pumping a gas into the first end of the glass capillary.

27. The method of claim 20, wherein (c) comprises applying an external pressure to the glass capillary by applying opposing compressive forces to at least one of:
portions of the glass capillary extending from the channel; and
one or both ends of the glass capillary.

28. The method of claim 27, wherein the opposing compressive forces are applied along a longitudinal direction of the glass capillary.

29. The method of claim 27, further comprising the step of inserting a rigid element into the glass capillary before applying the external pressure.

30. (canceled)

31. The method of claim 20, wherein a coefficient of thermal expansion of the glass capillary is less than or equal to a coefficient of thermal expansion of the metal fitting over a temperature range comprising an operational temperature range of the component and a manufacturing temperature range of the component.

32. The method of claim 24, wherein the metal fitting comprises molybdenum, tantalum, tungsten, or a metal alloy and/or the glass capillary comprises a borosilicate, an aluminosilicate, or quartz.

33. The method of claim 20, wherein at least a portion of the interior surface of the metal fitting comprises a metal oxide layer with the glass capillary being joined to the metal oxide layer.

34. The method of claim 20, further comprising annealing the glass capillary and/or the metal fitting after allowing the metal fitting to cool.

35. The method of claim 20, wherein heating the metal fitting comprises induction heating the first and second metal fittings and providing a flow of an inert gas during the induction heating, the flow directed to the glass capillary.

36.-47. (canceled)
